(19) United States
(12) Patent Application Publication
(10) Pub. No.: US 2013/0181248 A1
(43) Pub. Date: Jul. 18, 2013

(54) Optoelectronic Semiconductor Component

(71) Applicants: Angela Eberhardt, Augsburg (DE); Frank Jermann, Konigsbrunn (DE)

(72) Inventors: Angela Eberhardt, Augsburg (DE); Frank Jermann, Konigsbrunn (DE)

(21) Appl. No.: 13/825,900

(22) PCT Filed: Aug. 31, 2011
(86) PCT No.: PCT/EP11/64986

§ 371 Date: Mar. 25, 2013

(30) Foreign Application Priority Data
Sep. 23, 2010 (DE) 10 2010 041 236.8

(51) Int. Cl. H01L 33/44

(52) U.S. Cl. CPC H01L 33/44
USPC 257/98

(57) ABSTRACT

An optoelectronic semiconductor component comprising a light source, a housing and electrical connections, wherein the light source emits primary radiation having a peak wavelength in the range of 420 to 460 nm and having a flank of the primary emission which extends into the range less than 420 nm, wherein the radiation of the flank range or of part thereof is converted into visible radiation by an additive phosphor.

### TECHNICAL FIELD

The invention is based on an optoelectronic semiconductor component according to the preamble of claim 1, in particular a conversion LED. It also describes an associated production method.

### PRIOR ART

U.S. Pat. No. 5,998,925 discloses a typical white LED. Precisely in the case of conversion LEDs of this type, it is important for the primary emission to be relatively short-wave. The peak is typically at 440 to 460 nm. Since the full width at half maximum usually lies in a range of 20 to 40 nm, an LED of this type often still indeed emits appreciable portions of the radiation in a range below 420 nm. This radiation poses problems, however, since, owing to its high energy, it has a destructive effect on the component parts of the LED. One technique employed hitherto in order to be able to come to terms with this is the targeted use of organic materials having an increased UV resistance, but this results in only a limited choice of materials for selection.

### SUMMARY OF THE INVENTION

It is an object of the present invention, in the case of an optoelectronic semiconductor component according to the preamble of claim 1, to find an improved solution to the problem of the lack of UV resistance of materials.

This object is achieved by means of the characterizing features of claim 1.

Particularly advantageous configurations are found in the dependent claims.

The present invention solves said problem by converting the disadvantage into an advantage. It is thereby possible to obtain not only an improved UV protection for organic components or component parts of the LED, but also an increase in the efficiency in the case of LEDs for chips having a main emission at >420 nm.

Typically, a maximum of the emission is e.g. at approximately 440 nm (see e.g. FIG. 2). In this case, there also arises a small portion (approximately 10%) of short-wave UV radiation having wavelengths of <420 nm, which breaks open organic bonds such as C—C; C—H; C—O—O—H and leads to an undesirable discoloration. It is possible to “cut off”, that is to say absorb, this UV portion by means of a suitable optical filter (e.g. coating), and thereby to protect the plastic. The invention proposes that the short-wave UV radiation <420 nm, in particular the range of 380-420 nm, which is not optically usable and would lead only to undesirable heating, not be cut off by means of filters. Instead, this radiation can be converted into visible light by means of a suitable phosphor, the absorption of which is relatively high in this range, as a result of which not only does less heat arise, but the efficiency is also improved.

Preferably, a phosphor is used which is efficiently excited at 380-420 nm, in particular with the property that its QE and absorption are >50%, preferably >70%, ideally >80%. It is ideal if said phosphor emits in the visible range (>420 nm) similarly to the chip. In the case of a white LED, this is an additional phosphor component, in addition to the main phosphor component (in relation to light conversion) such as e.g. the YAG:Ce known per se, or some other garnet. The additional phosphor component can emit in the color of the chip (“chip color”), that is to say blue. Suitable phosphors are e.g. BAM or SCAP. However, the additive phosphor can also emit in the color of the main phosphor component or in other colors. This occurs, for example, when using e.g. silicates or oxynitrides which emit yellow or green. A mixture of the additional phosphor components is likewise conceivable. The additional (additive) phosphor component can be applied as a layer on the reflector and/or on the board.

The additional phosphor component can emit in the color of the chip (“chip color”), that is to say blue. Suitable phosphors are e.g. BAM or SCAP. However, the additive phosphor can also emit in the color of the main phosphor component or in other colors. This occurs, for example, when using e.g. silicates or oxynitrides which emit yellow or green. A mixture of the additional phosphor components is likewise conceivable. The additional (additive) phosphor component can be applied as a layer on the reflector and/or on the board.

In the case of a chip emission having main emission >420 nm, e.g. approximately 440 nm, the portion of short-wave UV radiation that unavoidably arises, in particular in the range of 380-420 nm, can be converted into usable radiation having a longer wavelength by means of an additional phosphor component. This leads to an increase in efficiency by virtue of more visible light and correspondingly less production of heat. Moreover, a larger number of plastics can be used, in principle, in this case. An additional factor as an option is an improvement in the emission characteristic of the LED.

The invention is suitable not only for conversion LEDs, whether full conversion or partial conversion, but also for pure LEDs, in particular for blue LEDs.

One particularly highly suitable additive phosphor or in the case for a pure LED of a single, efficiency-improving phosphor is M10(PO4)6Cl2:Eu where M=Sr, Ba, Ca alone or in combination. Sr10(PO4)6Cl2:Eu is particularly suitable. In this case, the doping Eu replaces M, preferably Sr, in part at the lattice sites thereof. A preferred doping is 3 to 6 mol % Eu.

Essential features of the invention in the form of a numbered enumeration are:
1. An optoelectronic semiconductor component comprising a light source, a housing and electrical connections, wherein the light source emits primary radiation having a peak wavelength in the range of 420 to 460 nm and having a flank of the primary emission which extends into the range less than 420 nm, characterized in that the radiation of the flank range or of part thereof is converted into visible radiation by an additive phosphor.
2. The optoelectronic semiconductor component as claimed in claim 1, characterized in that the additive phosphor converts radiation in the range of 380 to 420 nm into visible radiation at least partly and preferably as efficiently as possible.
3. The optoelectronic semiconductor component as claimed in claim 1, characterized in that the additive phosphor has the peak of its emission in the blue to yellow spectral range, in particular at 430 to 565 nm.
4. The optoelectronic semiconductor component as claimed in claim 1, characterized in that the light source is a conversion LED having a main phosphor.
5. The optoelectronic semiconductor component as claimed in claim 1, characterized in that the additive phosphor is applied on the chip and/or on side walls of the housing.
6. The optoelectronic semiconductor component as claimed in claim 1, characterized in that the additive phosphor is applied on the chip before the main phosphor or is mixed therewith.
7. The optoelectronic semiconductor component as claimed in claim 1, characterized in that the additive phosphor is selected from the group M10(PO4)6Cl2:Eu where M=Sr, Ba, Ca alone or in combination, (BaₓEu₁₋ₓ)MgAl₁₀O₁₇ where x=0.3 to 0.5, or (Sr_{1-x-y}CeₓLi_{y})₂Si₅N₈.

### BRIEF DESCRIPTION OF THE DRAWINGS

The invention will be explained in greater detail below on the basis of a number of exemplary embodiments. In the figures:

FIG. 1 shows a typical spectrum of the primary emission of an LED as a function of the operating current;

FIG. 2 shows the emission and absorption of a suitable phosphor;

FIG. 3 shows an LED which uses an additive phosphor;

FIGS. 4-7 each show a further exemplary embodiment of an LED which uses an additive phosphor.

### Preferred embodiment of the invention

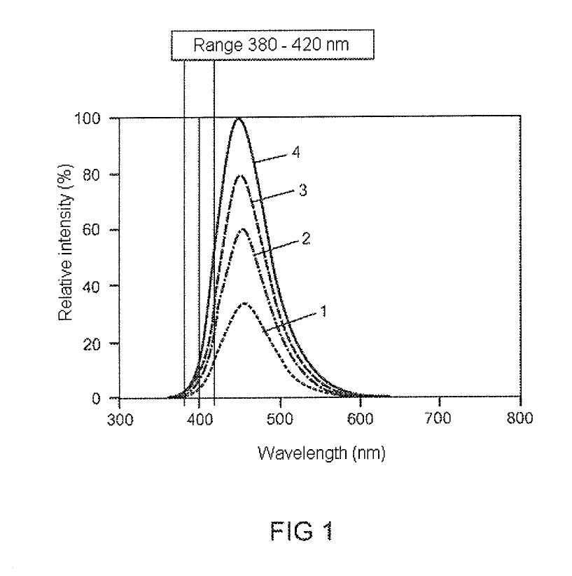

FIG. 1 shows the typical emission spectrum of an LED which can be used as a primary radiation source in a conversion LED. This usually involves an LED of the InGaN type. As the operating current increases, said operating current typically being 10 to 40 mA (curve 1: 10 mA, 2: 20 mA; curve 3: 30 mA; curve 4: 40 mA), the peak of the primary emission shifts in the direction of shorter wavelengths. At the same time there is an increase in the portion of the primary radiation in the short-wave flank of the emission below 420 nm. The aim of the invention is to make the range below 420 nm, primarily in the range of 380 to 420 nm, usable. Depending on the type and operating current, the portion in this window can be almost 10%. Application of the invention is expedient if said portion is at least 1%. The portion of said radiation which strikes the housing of the LED depends greatly on the chip type and the conversion technology possibly used. The portion is particularly high in the case of chips which emit blue and in this case are not designed as thin-film chips, that is to say, in particular, chips which emit from the volume, in which the light-emitting layer is applied on a sapphire substrate.

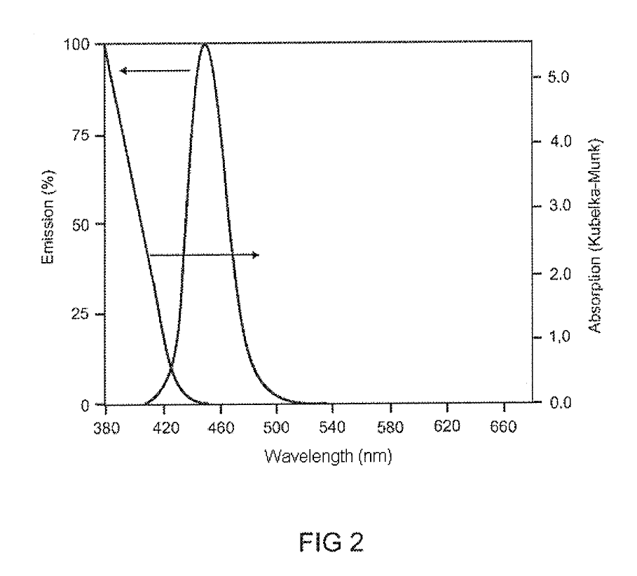

FIG. 2 shows an exemplary embodiment of a suitable phosphor which converts UV into blue. This involves (Sr0.96Eu0.04)10(PO4)6Cl2. This halophosphate exhibits high absorption precisely in the window range of 380 to 420 nm and emits in the blue, substantially in a range of 430 to 490 nm.

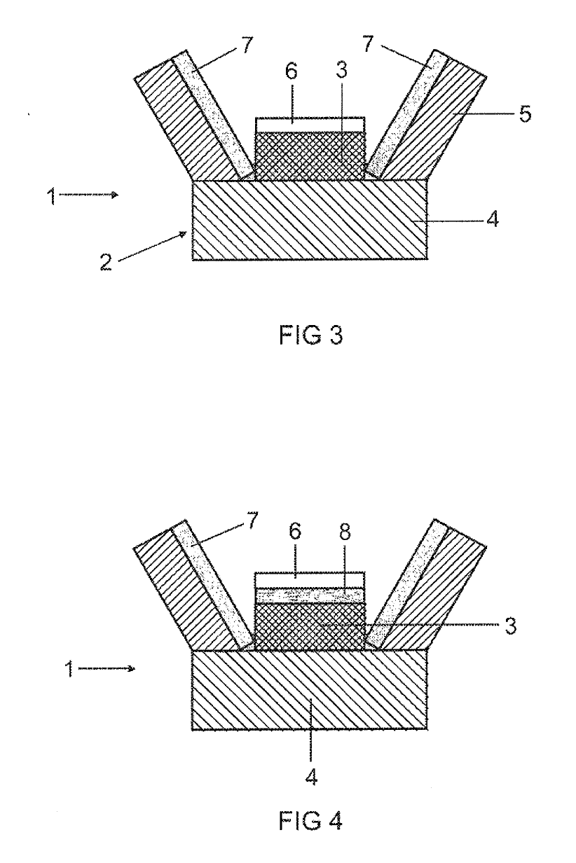

FIG. 3 schematically shows a basic schematic diagram of an LED 1. The LED has a housing 2, in which is seated a chip 3 of the InGaN type, which emits blue (peak at approximately 440 to 450 nm). In this case, the housing 2 of the LED has a board 4 and reflective side walls 5.

A main phosphor, in particular YAG:Ce or some other garnet, orthosilicate or sion, nitridosilicate, sialon, etc., is applied directly to the chip. An additive phosphor such as the abovementioned halophosphate is applied on the inside on the side walls 5. Further possible phosphors are (EA_{1-x-y}CeₓLi_{y})₂Si₅N₈ where EA=Sr, Ba, Ca, (BaₓEu₁₋ₓ)MgAl₁₀O₁₇ in particular having high Eu concentrations x=0.3 to 0.5, or else aluminates that can be excited in the near UV, such as (Sr₁₋ₓEuₓ)Al₁₂O₁₉.

In accordance with FIG. 4, the additive phosphor is additionally also applied to the chip 3. It preferably lies as a dedicated layer 8 below the main component 6.

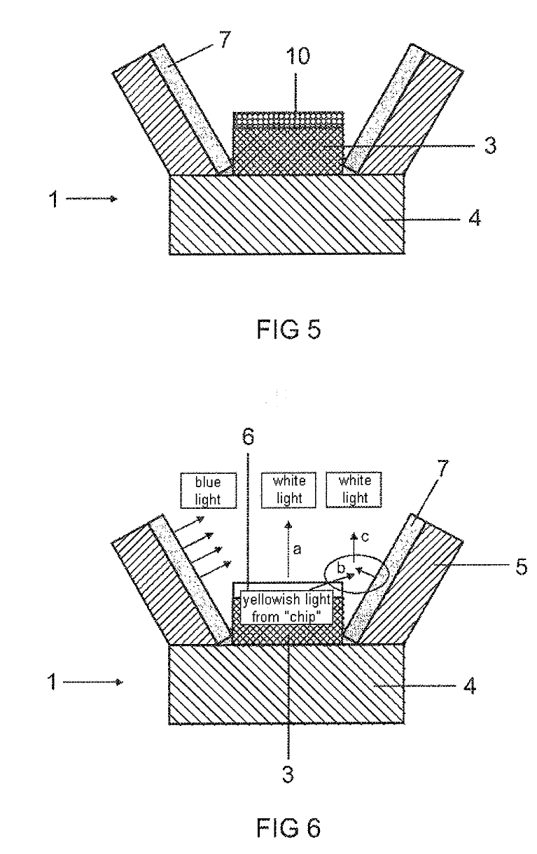

However, it can also be mixed with the main component in a single layer 10, see FIG. 5.

The additional phosphor can be present as a powder layer or can be fixed in a matrix. Said matrix can be organic or inorganic and is preferably UV-stable. By way of example, silicone or glass are suitable. Fixing in the surface of the plastic reflector by means of slight heating is also possible. The application process takes place by means of one of the customary methods known to the person skilled in the art, such as e.g. spraying, screen printing, dispensing etc., and, if appropriate, an adapted thermal treatment.

If a blue-emitting phosphor is chosen as additional component in the case of a white LED, then the “yellow” ring that often occurs can be at least partly converted into white light by mixing with the blue emission from the reflector, and thereby attenuated. If the additional phosphor component has reflective properties similar to those of the reflector material, the latter can be wholly or partly replaced thereby.

Particles that reflect and/or scatter light can also be mixed into the additional phosphor.

Ideally, additive phosphors (“UV converters”) are used which convert the radiation in the range of 380-420 nm with a high quantum efficiency of >80%, preferably >90%. In order to achieve a high conversion efficiency, moreover, the absorption of the coating should be as high as possible in the wavelength range of 380-420 nm.

In the case of conversion LEDs, it is advantageous for the efficiency of the LED if the relevant UV converter absorbs as little as possible in the range of the useful radiation of the LED (420 nm to, if appropriate, 780 nm).

Exemplary embodiments of an additive converter for the conversion of the UV portion into blue light are e.g. high-efficiency phosphors of the type (Ba_{0.4}Eu_{0.6})MgAl₁₀O₁₇, (Sr_{0.96}Eu_{0.04})₁₀(PO₄)₆Cl₂. An exemplary embodiment of an additive converter for the conversion of the UV portion into yellow light is e.g. (Sr_{1-x-y}CeₓLi_{y})₂Si₅N₈. In particular, x and y here are each in the range of 0.1 to 0.01. A phosphor (Sr_{1-x-y}CeₓLi_{y})₂Si₅N₈ in which x=y is particularly suitable.

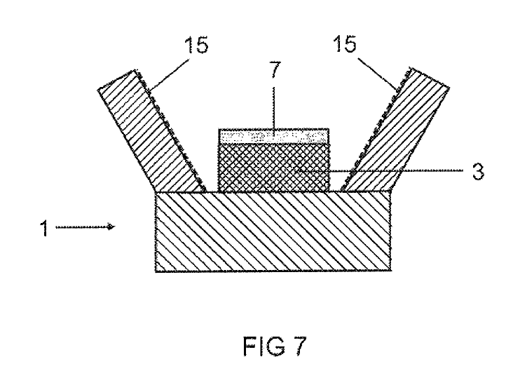

FIG. 6 shows an exemplary embodiment of an LED 1 which avoids the so-called yellow ring. In this case, the main phosphor, which emits yellow, in particular, is again seated on or else in front of the chip 3 in a layer 6. White light emerges frontally as a result of the mixing of the blue primary and yellow secondary radiation, arrow a. Instead of white rather yellow light emerges laterally from the conversion layer (arrow b) because the scattering behavior and emission behavior of the phosphor or of the matrix containing the phosphor differ. The yellowish light impinges principally on the side walls 5 and mixes with the blue light of the additive phosphor from the layer 7 applied there, such that white light is emitted in an outer ring region as well (arrow c), instead of the undesirable yellow ring occurring.

FIG. 7 shows an exemplary embodiment of an LED 1 (the component can also be a laser, in principle) in which a pure InGaN chip 2 without a main phosphor is used as the light source. It emits blue in a manner similar to that shown in FIG. 1. Disposed directly in front of it is an additive phosphor 7, to be precise without any main phosphor, here BAM, which converts the flank range of the primary emission into blue radiation, such that a particularly effective blue LED is realized. The side walls are provided here with a reflective coating 15 in a simple manner as known per se.

Essential points of the invention are:

The optoelectronic semiconductor component uses an additive phosphor which converts a flank range of the emission of the primary radiation source below 420 nm into visible radiation. The following are applicable, in particular:
chip emission with main emission >420 nm, in particular 425 to 450 nm, e.g. approximately 440 nm
arising short-wave UV<420 nm, preferably 380-420 nm, is not intended to be cut off by a filter, but rather converted into light. This leads to an increase in efficiency by virtue of more visible light and less formation of heat as a result.
preference is given to an additional blue-emitting phosphor which is excited as efficiently as possible at 380-420 nm and emits similarly to the chip, in particular (Sr0.96Eu0.04)10(PO4)6Cl2.
other additional phosphor colors are also suitable, in particular yellow-emitting phosphors, which is also excited efficiently at 380-420 nm; they are suitable as a dedicated variant or in combination with the blue additive phosphor.
the aim is to avoid or reduce the primary radiation <420 nm, preferably in the range of 380-420 nm, because this radiation is the most effective at breaking open organic bonds (C—C; C—H; C—O—O—H), which is precisely to be avoided. That leads to a greater diversity in the selection of plastics which can be used for the housing, and, if appropriate, to the use of more cost-effective plastics. These can be usable in particular as a board. Alternatively, this leads to a longer lifetime of the LED.
additive blue- and/or yellow-emitting phosphors are applied preferably in the reflector region of the board alone or in conjunction with reflector material (e.g. TiO2) in accordance with FIG. 3.
to supplement 6. the application process can also be effected on the chip, below the main phosphor (e.g. YAG) in accordance with FIG. 4 or in a manner mixed into said main phosphor in accordance with FIG. 5.
furthermore, it is possible to reduce or avoid the “yellow ring” as a result of blue emission from the reflector in accordance with FIG. 6.
if the additive blue- and/or yellow-emitting phosphors have reflective properties similar to those of the reflector material, the latter can be wholly or partly replaced thereby.

1. An optoelectronic semiconductor component comprising a light source, a housing and electrical connections, wherein the light source emits primary radiation having a peak wavelength in the range of 420 to 460 nm and having a flank of the primary emission which extends into the range less than 420 nm, wherein the radiation of the flank range or of part thereof is converted into visible radiation by an additive phosphor.

2. The optoelectronic semiconductor component as claimed in claim 1, wherein the additive phosphor converts radiation in the range of 380 to 420 nm into visible radiation at least partly and preferably as efficiently as possible.

3. The optoelectronic semiconductor component as claimed in claim 1, wherein the additive phosphor has a peak of its emission in the blue to yellow spectral range.

4. The optoelectronic semiconductor component as claimed in claim 1, wherein the light source is a conversion LED having a main phosphor.

5. The optoelectronic semiconductor component as claimed in claim 1, wherein the additive phosphor is applied on the chip and/or on side walls of the housing.

6. The optoelectronic semiconductor component as claimed in claim 1, wherein the additive phosphor is applied on the chip before the main phosphor or is mixed therewith.

7. The optoelectronic semiconductor component as claimed in claim 1, wherein the additive phosphor is selected from the group M10(PO4)6Cl2:Eu where M=Sr, Ba, Ca alone or in combination, (BaxEu1-x)MgAl10O17 where x=0.3 to 0.5, or (Sr1-x-yCexLiy)2Si5N8.

8. The optoelectronic component as claimed in claim 1, wherein the additive phosphor has a peak of its emission at 430 to 565 nm.
